(19) United States
(12) Patent Application Publication
(10) Pub. No.: US 2015/0249124 A1
(43) Pub. Date: Sep. 3, 2015

(54) SEMICONDUCTOR DEVICE AND ASSOCIATED FABRICATION METHOD

(71) Applicant: Chengdu Monolithic Power Systems Co., Ltd., Chengdu (CN)

(72) Inventors: Rongyao Ma, Chengdu (CN); Tiesheng Li, San Jose, CA (US); Donald Disney, Cupertino, CA (US); Lei Zhang, Chengdu (CN)

(21) Appl. No.: 14/715,404

(22) Filed: May 18, 2015

Related U.S. Application Data
(63) Continuation of application No. 13/787,689, filed on Mar. 6, 2013.

(30) Foreign Application Priority Data
Mar. 7, 2012 (CN) 201210057865.2

(51) Int. Cl. H01L 29/06; H01L 29/66; H01L 29/78

(52) U.S. Cl. CPC H01L 29/0634; H01L 29/7813; H01L 29/66734

(57) ABSTRACT

A super junction structural semiconductor device with a substantially rectangle-shaped first region, and a second region surrounding the periphery of the first region; trench gate MOSFET units in the first region comprising a plurality of trench gate regions and a first plurality of pillars; a body region between the trench gate regions and the first plurality of pillars; a second plurality of pillars in the second region extending along a corresponding side of the first region comprising a plurality of lateral pillars and a plurality of longitudinal pillars, wherein in a corner part of the second region, ends of the plurality of lateral pillars and ends of the plurality of longitudinal pillars are stagger and separated apart from each other.

### CROSS-REFERENCE TO RELATED APPLICATION(S)

This application is a continuation of U.S. patent application Ser. No. 13/787,689, filed on Mar. 6, 2013, entitled “SEMICONDUCTOR DEVICE AND ASSOCIATED FABRICATION METHOD,” which claims the benefit of CN application No. 201210057865.2, filed on Mar. 7, 2012, both of which are hereby incorporated by reference in their entirety.

### TECHNICAL FIELD

The present invention generally relates to semiconductor technology, and more particularly but not exclusively relates to a super junction semiconductor device and associated fabrication method.

### BACKGROUND

Super junction structure may reduce the product of on-state resistance Ron and area A, and thus be widely utilized in small scale device. FIG. 1 illustrates a layout view of a prior art super junction device. Generally, a super junction device comprises a main cell region and a termination region formed on a die. A primary part of the semiconductor device is formed in the main cell region, and the terminals of the semiconductor device are lead out by the termination region.

For super junction device, since the charge at the corner of P-type or N-type pillar is imbalanced, it may be easy to cause breaking down at the corner of the super junction die, as shown in the dash line frame of FIG. 1. FIG. 2A and FIG. 2B illustrate enlarged views of the corner of the super junction device shown in FIG. 1. Wherein, FIG. 2A illustrates a layout view of a conventional arc-shaped P-type pillar 201. FIG. 2B illustrates a layout view of a conventional longitudinal and joint P-type pillar 202. In addition, as it is hard to put the trench gate and P-type pillar at the edge part of the main cell region, the charge is imbalanced. Therefore, improvement of the super junction device is required to reach a charge balance.

### SUMMARY

One embodiment of the present invention discloses a semiconductor device, comprising: a die; a substantially rectangle-shaped first region, and a second region in the periphery of the first region, wherein both the first region and the second region are formed on the die; trench gate MOSFET units, formed in the first region, the trench gate MOSFET units comprising a plurality of trench gate regions and a first plurality of pillars, wherein each of the first plurality of pillars separates two adjacent trench gate regions; a body region formed among the trench gate regions and the first plurality of pillars, wherein each of the first plurality of pillars has two ends; and a second plurality of pillars, formed in the second region, the second plurality of pillars extending along a corresponding side of the first region, the second plurality of pillars comprising a plurality of lateral pillars and a plurality of longitudinal pillars, wherein each of the plurality of lateral pillars and the plurality of longitudinal pillars has two ends, and wherein in a corner part of the second region, ends of the lateral pillars and ends of the longitudinal pillars are stagger and separated apart from each other.

The embodiment described above may achieve the charge balance at corner part by forming pillars with a stagger structure at the corner part and keeping a certain spacing for each pillar. With such design, the corner part avoids to be broken down firstly, so the breakdown voltage of the device is improved.

### BRIEF DESCRIPTION OF THE DRAWINGS

Non-limiting and non-exhaustive embodiments are described with reference to the following drawings. The drawings are not depicted to scale and only for illustration purpose.

FIG. 1 illustrates a layout view of a super junction device as a prior art.

FIG. 2A illustrates a layout view of a corner part of the super junction device shown in FIG. 1 as a prior art.

FIG. 2B illustrates another layout view of a corner part of the super junction device shown in FIG. 1 as a prior art.

FIG. 3 schematically illustrates a layout view of a semiconductor device 300 and an enlarged view of its corner part according to an embodiment of the present invention.

FIG. 4 schematically illustrates a layout view of the semiconductor device 300 shown in FIG. 3 and an enlarged view of its edge part of the main cell region 310 according to an embodiment of the present invention.

FIG. 5 schematically illustrates a cross-sectional view of the semiconductor device shown in FIG. 4 along with line A-A′ in FIG. 4 according to an embodiment of the present invention.

FIG. 6 schematically illustrates a process flow of a fabrication method 600 for forming a semiconductor device according to an embodiment of the present invention.

The use of the same reference label in different drawings indicates the same or like components.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

In the following text, the term “substrate” includes but not limited to a variation types of dies, e.g. monolithic integrated circuit die, sensor die, switch die and any other die with semiconductor property.

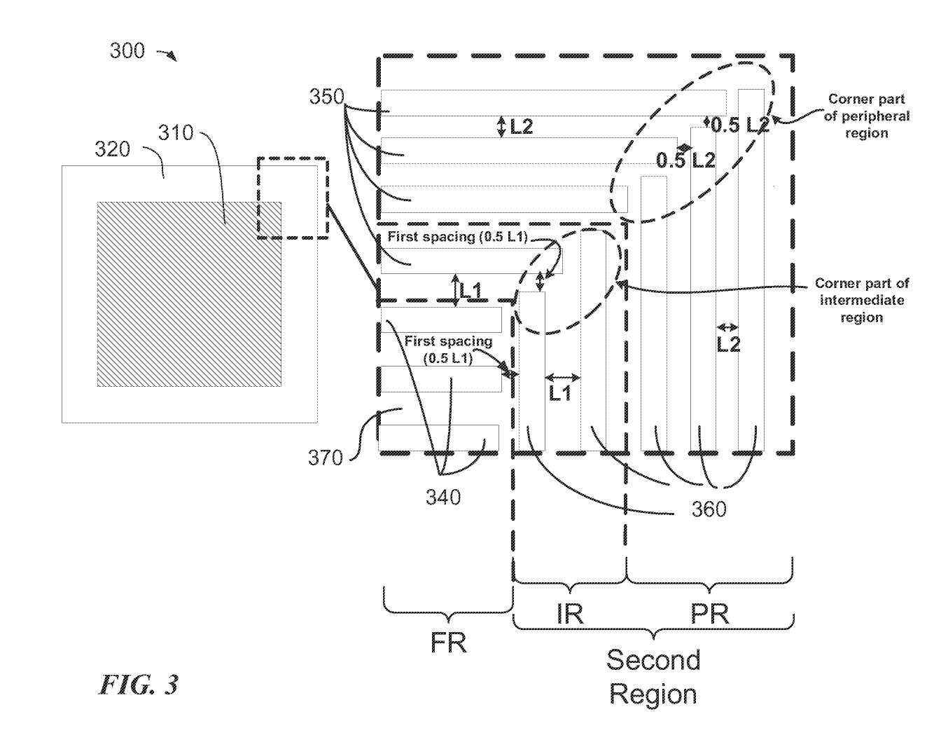

FIG. 3 illustrates a layout view of a semiconductor device 300 and an enlarged view of its corner part according to an embodiment of the present invention. The following description will take power device as an example. However, one skilled in the art should understand that it is not intended to limit the present invention to power device. The present invention may also be applied in other suitable types of device.

As shown in FIG. 3, semiconductor device 300 according to the present embodiment comprises a main cell region 310 and a termination region 320. Generally, a primary part of the semiconductor device is formed in the main cell region, and the terminals of the semiconductor device are lead out by the termination region. In the layout view of semiconductor device 300 shown in FIG. 3, the main cell region 310 and the termination region 320 are rectangle-shape. However, one skilled in the art should understand other shape, e.g. square, may also be applied in other embodiments.

See the right part of FIG. 3, in the enlarged view, the super junction device comprises a first region FR, an intermediate region IR as a second region, and a peripheral region PR, wherein the first region FR and the intermediate region IR constitute main cell region 310, and wherein the peripheral region PR constitute termination region 320. However, one skilled in the art could understand that in other embodiments, the first region FR may constitute the main cell region 310; and the intermediate region IR and the peripheral region PR may constitute the termination region.

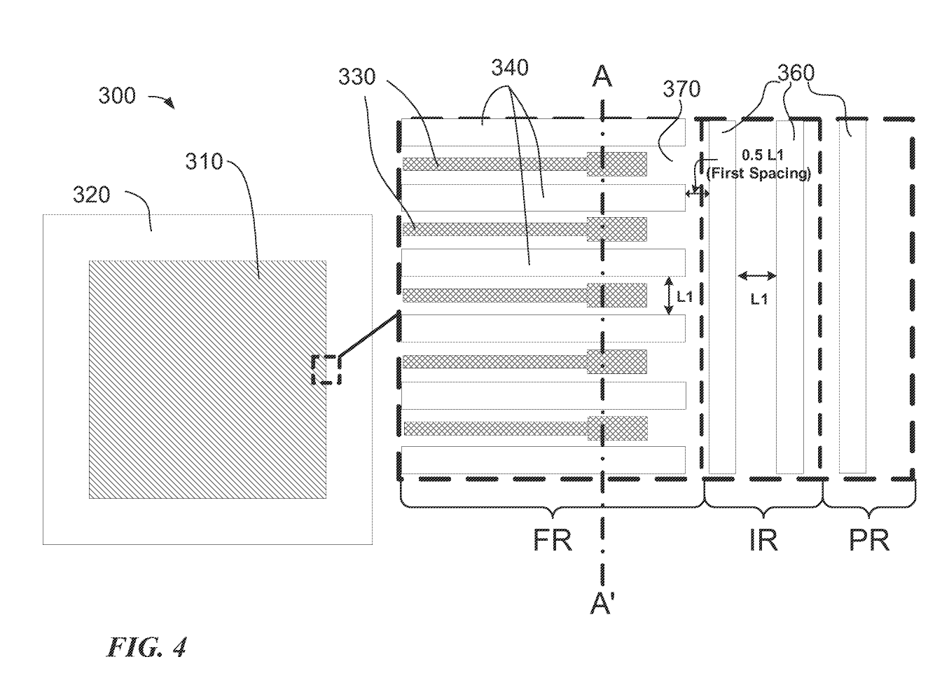

In one embodiment, trench gate metal oxide semiconductor field effect transistor (MOSFET) units comprising a first plurality of trench regions 330 and a first plurality of pillars 340 are formed in the first region FR, as depicted in FIG. 3 and FIG. 4. Each of the first plurality of pillars 340 has two ends. Each of the first plurality of pillars 340 separates two adjacent trench regions 330, and a body region 370 is formed among the trench regions 330 and the first plurality of pillars 340. A second plurality of pillars, which comprise a plurality of lateral pillars 350 and a plurality of longitudinal pillars 360, extending along with the corresponding side of the first region FR are also formed in intermediate region IR and peripheral region PR. Each of the lateral pillars 350 and longitudinal pillars 360 has two ends. In a corner part of the second region, ends of the plurality of lateral pillars 350 and ends of the plurality of longitudinal pillars 360 are stagger and separated apart from each other. The spacing between the two adjacent pillars in the first region FR and in the intermediate region IR (main cell region 310) both equal to L1. And the spacing between two adjacent pillars in the peripheral region PR equals to L2.

In a low voltage super junction device, since the pillars in the device are relatively shallow, the charge of the P-type body region 370 could not be ignored compared with the charge of the pillars. If the spacing L2 between two adjacent pillars in termination region 320 (peripheral region PR) keeps the same as the spacing between adjacent pillars in main cell region 310 (the first region FR and the intermediate region IR), the charge may be imbalanced. Therefore, the spacing L2 between two adjacent pillars in termination region 320 is set to be smaller than the spacing L1 between two adjacent pillars in main cell region 310.

However, one skilled in the art could understand that in high voltage super junction device, the spacing L1 between two adjacent pillars in the intermediate region IR and the first region FR may be the same as the spacing L2 between two pillars in the periphery region PR.

According to the illustrated embodiment shown in FIG. 3, in a corner part of the intermediate region IR, each end of the lateral pillars 350 separates apart from the nearest longitudinal pillar 360 for a first spacing, wherein the first spacing is substantially half of the spacing L1 between the two adjacent longitudinal pillars 360 of the intermediate region IR. In a corner part of the peripheral region PR, each end of the lateral pillars 350 separates apart from the nearest longitudinal pillar 360 for a second spacing, wherein the second spacing is substantially half of the spacing L2 between the two adjacent longitudinal pillars 360 of the peripheral region PR.

The right part of FIG. 4 illustrates an enlarged view of a square region across the main cell region 310 and the termination region 320. Seen in FIG. 4, the trench gates 330 and the first plurality of pillars 340 are formed in alternate pattern in the first region FR. Each of the first plurality of pillars 340 separates two adjacent trench gates 330 in trench gate MOSFET units.

In the edge part of the main cell region, the spacing between each end of the first plurality of pillars 340 in the first region FR and the nearest longitudinal pillar 360 in the intermediate region IR is set to be the first spacing which is substantially half of the spacing L1.

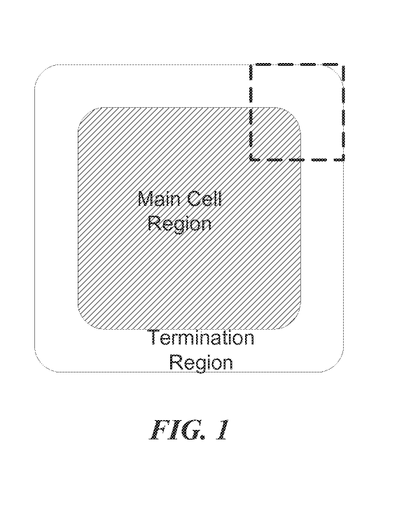

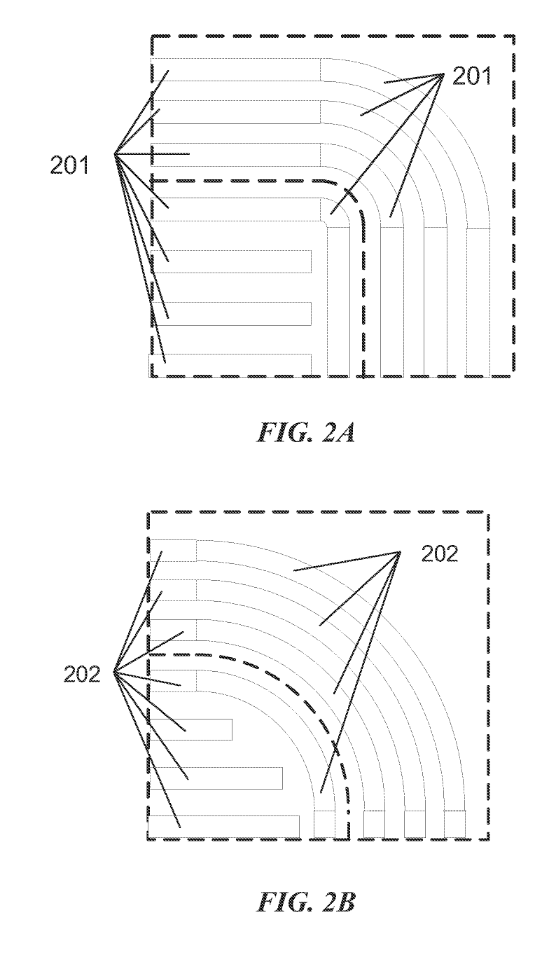

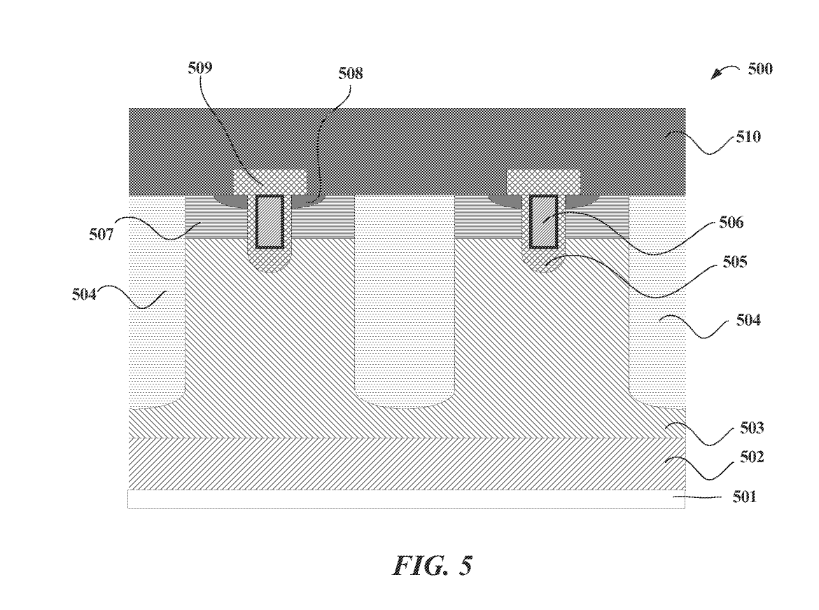

FIG. 5 schematically illustrates a cross-sectional view of the semiconductor device shown in FIG. 1 along with line A-A′ in FIG. 1. Seen in FIG. 5, semiconductor device 500 comprises a semiconductor substrate 502, a metal layer 501 formed at a backside of semiconductor substrate 502, an epitaxy layer 503 formed on the semiconductor substrate 502, deep wells 504 formed in epitaxy layer 503, and trench gate MOSFET units formed in the epitaxy layer 503 between the deep wells 504.

A body region 507 formed in top of the epitaxy layer 503. The semiconductor substrate 502 serves as drain region. Each of the trench gate MOSFET unit comprises a source region 508 and a shallow trench gate both formed in the body region 507, wherein the depth of the shallow trench gate is no more than half or even one third of the spacing of two adjacent deep wells, configured to lower down the density of trench gate and to reduce the gate charge Qg.

According to another embodiment, a thick oxide layer is formed on the sidewall and the bottom of the shallow trench gate, and the shallow trench gate is further filled with poly silicon layer 506.

In this embodiment, a gate oxide layer 509 and a metal layer as source electrode 510 are formed on the trench gate, which establishes an electrical connection from the gate poly silicon to outside through vias. In addition, a metal layer 501 is also formed on the backside of the semiconductor substrate as drain electrode.

In the illustrated embodiment, the body region 507 may be positioned on the deep wells 504 so that the portions of body region of adjacent trench gate MOSFET units are connected with each other. However, in another embodiment, the deep wells 504 may separate portions of body region 507 of adjacent MOSFET units. Body region 507 is formed as shallow body region and light doped. In yet another embodiment, body region 507 is formed by applying two ion implantation steps of light doping.

The super junction device according to above embodiments may significantly reduce the product of on-state resistance Ron and gate charge Qg (Ron×Qg). Besides, this improvement of super junction technology may also reduce the product of on-state resistance Ron and area A (Ron×A). Therefore the semiconductor device according to these embodiments is proper to be applied into the area of high voltage high speed circuit.

To achieve a high accuracy doping distribution, in certain embodiments, a plurality of ion implantation steps in epitaxy layer 503 are applied to form the deep wells 504. The dose of the deepest implantation step is higher than other implantation. For example, the dose of deepest implantation step is 105%-110% of the dose of other implantations. Thus more charges are provided to the bottom of the deep wells 504 for bottom charge compensation. In some embodiments, epitaxy layer 503 is formed by a plurality of epitaxial growth steps, and followed by a plurality of ion implantation steps for each epitaxial growth step, so that a relatively excellent doping distribution of deep wells 504 may be obtained. In other embodiment, the thicknesses formed in the plurality of epitaxial growth steps are different, and wherein the thickness formed in the first epitaxial growth step is larger than that in any other epitaxial layer growth steps.

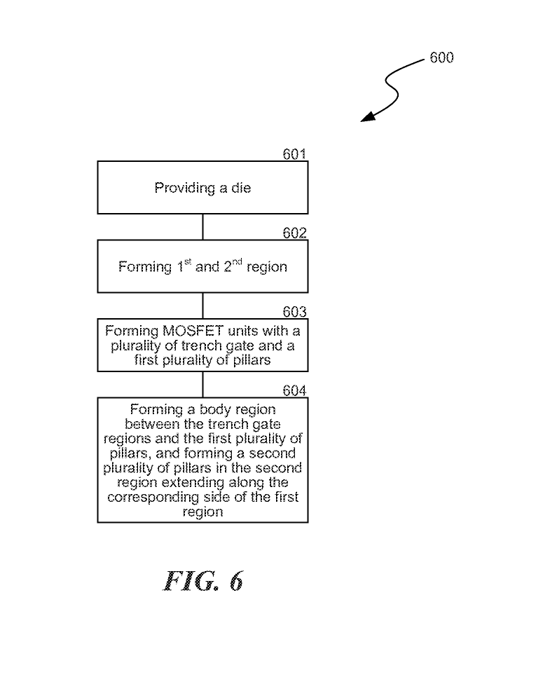

FIG. 6 schematically illustrates a process flow of a fabrication method 600 for forming a semiconductor device according to an embodiment of the present invention. As shown in FIG. 6, the method for forming semiconductor device according to an embodiment of the present invention comprises:

Step 601: providing a die;

Step 602: forming a substantially rectangle-shaped first region, and forming a second region surrounding the periphery of the first region, wherein the second region comprises an intermediate region and a peripheral region;

Step 603: forming a plurality of trench gate regions and a first plurality of pillars of trench gate MOSFET units, wherein each of the first plurality of pillars has two ends, and wherein each of the first plurality of pillar 320 separates two adjacent trench gate regions; and

Step 604: forming a body region among the trench gate regions and the first plurality of pillars, and forming a second plurality of pillars in the second region extending along the corresponding side of the first region, and wherein the second plurality of pillars comprise a plurality of lateral pillars and a plurality of longitudinal pillars, wherein each of the plurality of lateral pillars and the plurality of longitudinal pillars has two ends, and further wherein in a corner of the second region, the ends of a plurality of lateral pillars and a plurality of longitudinal pillars are stagger and separated with each other.

According to another embodiments, in the corner of the intermediate region, each end of the lateral pillars separates apart from the nearest longitudinal pillar for a first spacing, wherein the first spacing is substantially half of a spacing L1 between the two adjacent longitudinal pillars in the intermediate region. In the corner of the peripheral region, each end of the lateral pillars separates apart from the nearest longitudinal pillar for a second spacing, wherein the second spacing is substantially half of the spacing between the two adjacent longitudinal pillars in the periphery region.

In one embodiment, the first spacing L1 is larger than the second spacing L2. In another embodiment, the first spacing L1 is the same as the second spacing L2.

In yet another embodiment, each end of the first plurality of pillars separates apart from the nearest longitudinal pillar for half of the spacing L1 between the two adjacent first plurality of pillars.

For the issue that it is difficult to achieve the charge balance between the N-type pillar and the P-type pillar at the corner part of a conventional super junction device, the embodiments described above achieve the charge balance at corner part by forming pillars with a stagger structure at the corner part and keeping a certain spacing for each pillar. With such design, the corner part avoids to be broken down firstly, so the breakdown voltage of the device is improved.

Although the specification proposes some embodiments, it should not be understood as a limitation of the present invention. By reading the above text, one skilled in relevant art may master transformations or variations other than the described embodiments. For example, the above embodiments take n-channel device as example, however, by change the conductivity types of semiconductor region, the embodiments of the present invention may also applied in p-channel device. Therefore these transformations or variations should be included in the scope of protection of the present invention.

The above description and discussion about specific embodiments of the present invention is for purposes of illustration. However, one with ordinary skill in the relevant art should know that the invention is not limited by the specific examples disclosed herein. Variations and modifications can be made on the apparatus, methods and technical design described above. Accordingly, the invention should be viewed as limited solely by the scope and spirit of the appended claims.

I/We claim:

1. A semiconductor device, comprising:
a die;
a substantially rectangle-shaped first region, and a second region surrounding the periphery of the first region, wherein both the first region and the second region are formed on the die;
trench gate MOSFET units, formed in the first region, the trench gate MOSFET units comprising a plurality of trench gate regions and a first plurality of pillars, wherein each of the first plurality of pillars separates two adjacent trench gate regions;
a body region formed among the trench gate regions and the first plurality of pillars, wherein each of the first plurality of pillars has two ends; and
a second plurality of pillars, formed in the second region, the second plurality of pillars extending along a corresponding side of the first region, the second plurality of pillars comprising a plurality of lateral pillars and a plurality of longitudinal pillars, wherein each of the plurality of lateral pillars and the plurality of longitudinal pillars has two ends, and wherein in a corner part of the second region, ends of the lateral pillars and ends of the longitudinal pillars are stagger and separated apart from each other.

2. The semiconductor device according to claim 1, wherein in the corner part of the second region, each end of the lateral pillars separates apart from the nearest longitudinal pillar for a first spacing, wherein the first spacing is substantially half of the spacing between two adjacent longitudinal pillars.

3. The semiconductor device according to claim 2, wherein each end of the first plurality of pillars separates apart from the nearest longitudinal pillar for the first spacing.

4. The semiconductor device according to claim 1, wherein the second region comprises:
an intermediate region which is near the first region; and
a peripheral region which is far from the first region;
wherein the spacing among the second plurality of pillars formed in the intermediate region is larger than the spacing among the second plurality of pillars formed in the peripheral region.

5. The semiconductor device according to claim 4, wherein in a corner part of the intermediate region, each end of the lateral pillars separates apart from the nearest longitudinal pillar for a first spacing, and wherein the first spacing is substantial half of the spacing between the two adjacent longitudinal pillars.

6. The semiconductor device according to claim 4, wherein in a corner part of the peripheral region, each end of the lateral pillars separates apart from the nearest longitudinal pillar for a second spacing, and wherein the second spacing is substantial half of the spacing between the two adjacent longitudinal pillars.

7. The semiconductor device according to claim 6, wherein the second spacing is smaller than the first spacing.

8. The semiconductor device according to claim 6, wherein the second spacing is the same as the first spacing.

9. The semiconductor according to claim 4, wherein the first region and the intermediate region constitute a main cell region of the semiconductor device, and wherein the peripheral region constitutes a termination region of the semiconductor device.

10. A method for forming a semiconductor device, comprising:
providing a die;
forming a substantially rectangle-shaped first region on the die, and forming a second region on the die surrounding the periphery of the first region wherein the second region comprises an intermediate region and a peripheral region;
forming trench gate MOSFET units in the first region, wherein the trench gate MOSFET units comprise a plurality of trench gate regions and a first plurality of pillars, wherein each of the first plurality of pillars has two ends, wherein each of the first plurality of pillar separates two adjacent trench gate regions;
forming a body region among the trench gate regions and the first plurality of pillars; and
forming a second plurality of pillars in the second region, wherein the second plurality of pillars extend along a corresponding side of the first region, and wherein the second plurality of pillars comprise a plurality of lateral pillars and a plurality of longitudinal pillars, wherein each of the plurality of lateral pillars and the plurality of longitudinal pillars has two ends, and further wherein in a corner part of the second region, ends of the plurality of lateral pillars and ends of the plurality of longitudinal pillars are stagger and separated apart from each other.

11. The method for forming a semiconductor device according to claim 10, wherein in the corner part of the intermediate region, each end of the lateral pillars separates apart from the nearest longitudinal pillar for a first spacing, wherein the first spacing is substantially half of the spacing between the two adjacent longitudinal pillars in the intermediate region.

12. The method for forming a semiconductor device according to claim 11, wherein in the corner part of the peripheral region, each end of the lateral pillars separates apart from the nearest longitudinal pillar for a second spacing, wherein the second spacing is substantially half of the spacing between the two adjacent longitudinal pillars in the intermediate region in the peripheral region.

13. The method for forming a semiconductor device according to claim 12, wherein the second spacing is smaller than the first spacing.

14. The method for forming a semiconductor device according to claim 12, wherein the second spacing is the same as the first spacing.

15. The method for forming a semiconductor device according to claim 11, wherein each end of the first plurality of pillars separates apart from the nearest longitudinal pillar for the first spacing.
